(19) United States
(12) Patent Application Publication
(10) Pub. No.: US 2014/0342571 A1
(43) Pub. Date: Nov. 20, 2014

(54) WAFER ETCHING APPARATUS AND WAFER ETCHING METHOD USING THE SAME

(71) Applicant: RORZE SYSTEMS CORPORATION, Yongin-si, Gyeonggi-do (KR)

(72) Inventors: Saeng-Man Park, Suwon-si (KR); Seung-Bae Oh, Seongnam-si (KR)

(73) Assignee: RORZE SYSTEMS CORPORATION, Yongin-si, Gyeonggi-do (KR)

(21) Appl. No.: 14/366,196

(22) PCT Filed: Oct. 23, 2012
(86) PCT No.: PCT/KR2012/008719

§ 371 Date: Jun. 17, 2014

(30) Foreign Application Priority Data
Dec. 29, 2011 (KR) 10-2011-0146511

(51) Int. Cl. H01L 21/3065; H01L 21/683; H01L 21/67

(52) U.S. Cl. CPC H01L 21/3065; H01L 21/67069; H01L 21/6833
USPC 438/714; 156/345.38; 156/345.33

(57) ABSTRACT

A wafer etching apparatus and a wafer etching method using the wafer etching apparatus, which are capable of etching Si wafer in a dry etching method, are disclosed. According to the wafer etching apparatus and the wafer etching method, the capacitively coupled plasma unit or the inductively coupled plasma unit and the remote plasma unit are included together to etch wafer in a high speed and to reduce etching operation time. Additionally, the chuck has an upper surface with roughness so that the wafer can be cooled down through a helium gas provided to the wafer through a minute space between the upper surface and the wafer. Therefore, unwanted plasma which is generated in the groove in the conventional wafer etching apparatus is prevented to prevent damage of the wafer.

### TECHNICAL FIELD

The present invention relates to a wafer etching apparatus and a wafer etching method using the same, and more particularly to a wafer etching apparatus capable of etching Si wafer in a high speed through a dry etching method and a wafer etching method using the same.

### BACKGROUND

In general, in order to form wafer with a thickness of 30 μm or less, a back grinding process grinding backside surface of a wafer in a mechanical method and a chemical mechanical polishing (CMP) process, a wet etching process for forming Cu Pillar for wiring, etc. are performed together.

However, the above method has not only a problem of wafer breakage, warpage, thermal damage, etc. due to mechanical contact and stress induced by frictional heat, but also a problem of surface remaining stress when polishing.

Further, as a wafer becomes thinner, there exist complex problems such as a wafer handling problem, complexity of process, etc. to increase cost.

Therefore, a process, in which mechanical grinding is performed first until the wafer has a thickness of 100 μm to 200 μm, which is less damaged, and then dry etching is performed to reduce thickness and forming Cu pillar for connecting chips are performed, is under development.

According to a conventional dry etching process, CxFy gas or SxFy gas is used as main reaction gas and N₂, Ar, O₂, etc. gas is used as a sub gas. In a low pressure of a number of mTorr to hundreds of mTorr, a plasma source is applied from above and RF power of tens of KHz to GHz is applied to a lower chuck to generate plasma so that wafer etching process is performed by a chemical reaction.

However, the conventional dry etching process is performed in a low pressure, so that when a wafer with thick thickness requires much time to be etched so that productivity is lowered.

Additionally, one of important factors, in etching process through which wafer becomes thin, is high temperature generated in etching process. In a conventional etching process, an electro static chuck (ESC) is used for cooling down a wafer. In the conventional etching process, various chuck design is applied per wafer etching apparatus for cooling since each process has different characteristics.

Conventionally, the chuck has a circular disc shape with a plurality groove or a plurality of holes formed on an upper surface, and helium gas is applied to the heated wafer through the groove and holes.

On the other hand, etching process is performed to a wafer with a wafer carrier attached thereto since wafer carrying problem, and the wafer carrier is separated from the wafer when etching process is finished. In order to separate the wafer carrier from the wafer easily, the wafer carrier has a plurality of minute holes.

Therefore, when RF power is applied to the wafer on the conventional chuck to generate plasma, unwanted plasma is generated in the space between the wafer and the holes and groove to damage the wafer.

### DISCLOSURE

### Technical Problem

Therefore, the object of the present invention is to provide a wafer etching apparatus capable of etching Si wafer in a high speed by a capacitively coupled plasma unit or an inductively coupled plasma unit with remote plasma unit having a ferrite core with inductive coil, and a wafer etching method using the wafer etching apparatus.

The other object of the present invention is to provide a wafer etching apparatus capable of preventing unwanted plasma damaging a wafer, and a wafer etching method using the wafer etching apparatus.

### Technical Solution

A wafer etching apparatus according to an embodiment of the present invention includes a process chamber having a chuck disposed therein to support a wafer, a first plasma unit being connected to the process chamber and spraying a first etching gas of high pressure into the process chamber to etch the wafer with large surface in a high speed, and a second plasma unit being connected to the process chamber and spraying a second etching gas of low pressure into the process chamber to remove stress of the wafer, to form copper pillar, and to etch the surface of the wafer in order to form wanted roughness.

For example, the first plasma unit may be a remote plasma unit having a ferrite core with inductive coil.

For example, the first etching gas may include at least one of NF₃ and SF₆.

For example, the second plasma unit may be a capacitively coupled plasma (CCP) unit generating plasma between two parallel plates.

Alternatively the second plasma unit may be a an inductively coupled plasma (ICP) unit generating plasma through coil.

On the other hand, the wafer etching apparatus may further include a duct with a plurality of gas outlets through which the first etching gas is uniformly sprayed into the process chamber from the first plasma unit.

Additionally, the chuck may be disposed in the process chamber, and may have an upper surface with irregular roughness to generate minute space between the upper surface and the wafer, through which a cooling gas is provided to the wafer to cool down the wafer.

For example, the chuck may include an upper body supporting the wafer, the upper body having the upper surface with irregular roughness, and a lower body, on which the upper body is disposed, the lower body including a water providing line formed inside thereof.

For example, the upper surface of the upper body may include a minute space portion formed at a portion except a peripheral region to have irregular roughness so that the minute space is generated between the wafer and the minute space portion, and a contact portion formed at the peripheral region such that the contact portion has more dense and minute surface than the minute space portion to prevent the cooling gas for cooling from being deflated from the minute space.

A wafer etching method according to an example of the present invention include etching a wafer with large area by spraying a first etching gas with high pressure through a first plasma unit into a process chamber in which a wafer is disposed, etching the wafer by spraying a second etching gas with low pressure through a second plasma unit into the process chamber together with the first etching gas, and removing a stress of the wafer, forming a copper pillar and etching the wafer to form wanted roughness on a surface of the wafer through only the second etching gas at the same time by stopping an operation of the first plasma unit.

For example, etching the wafer by spraying the first etching gas and the second etching gas into the process chamber may include spraying the second etching gas into the process chamber through the second plasma unit together with the first etching gas, with lowering pressure of the process chamber, and gradually increasing the spraying amount of the second etching gas is gradually increased to etch the wafer, with gradually lowering the pressure of the chamber and gradually reducing the spraying amount of the first etching gas.

For example, it is preferable that spraying of the first etching gas is stopped, when the pressure of the process chamber is lowered to the pressure in which plasma may be generated by the second plasma unit.

On the other hand, it is preferable that the second etching gas is sprayed uniformly, when spraying of the first etching gas is stopped.

### Advantageous Effects

According to the wafer etching apparatus and the wafer etching method using the wafer etching apparatus of an embodiment of the present invention, the wafer etching apparatus includes the first plasma unit that is one of the capacitively coupled plasma unit or the inductively coupled plasma unit together with the second plasma unit that is a remote plasma unit having a ferrite core with an inductive coil to firstly etch a wafer in a high speed by the first plasma unit and then to remove stress of the wafer, to form the copper pillar by the second plasma unit and to secondly etch the wafer in order to form roughness at the surface of the wafer at the same time so that etching of the wafer can be performed in a high speed.

Therefore, according to the wafer etching apparatus and the wafer etching method using the wafer etching apparatus of an embodiment of the present invention, process time for wafer etching is reduced.

Further, unlike a conventional wafer etching apparatus cooling down a wafer through a cooling gas through groove of a chuck, the chuck of the wafer cooling apparatus of the present invention has an upper surface with roughness to form a minute space between the upper surface and the wafer, through which helium gas for cooling is provided to the wafer so that unwanted plasma which is generated in the groove in the conventional wafer etching apparatus is prevented.

### DESCRIPTION OF DRAWINGS

FIG. 1 is a perspective view showing a wafer etching apparatus according to an embodiment of the present invention.

FIG. 2 is a cross-sectional view showing inside of a wafer etching apparatus according to an embodiment of the present invention.

FIG. 3 is a plan view showing a chuck according to an embodiment of the present invention.

FIG. 4 is a cross-sectional view for explaining a chuck according to an embodiment of the present invention.

FIG. 5 is a figure for explaining a state where a minute space is formed between a wafer and a chuck.

FIG. 6 is a flow chart of a wafer etching method using a wafer etching apparatus according to an embodiment of the present invention.

FIG. 7 is a flow chart for explaining a step of wafer etching by spraying first and second etching gas simultaneously into a process chamber.

### MODE FOR INVENTION

This invention may be embodied in many different forms, and will be described with reference to the accompanying drawings. But this invention should not be construed as limited to the embodiments set forth herein, but should be understood to include every modifications, equivalents and substitutes

The terms such as ‘first’, ‘second’, etc. may be used for various elements but the elements should not limited by the terms. The terms may be used only for discriminating one element from others. For example, a first element may be named as a second element, and the second element may be named as the first element within the present invention.

The terms used in the present application are only to explain the specific embodiment and is not intended to limit the present invention. The terms “a”, “an” and “the” mean “one or more” unless expressly specified otherwise. The terms “including”, “comprising”, etc., are to designate features, numbers, processes, structural elements, parts, and combined component of the application, and should be understood that it does not exclude one or more different features, numbers, processes, structural elements, parts, combined component.

The technical term or the scientific term that will be used in the specification has the same meaning as a person skilled in the art commonly understood unless defined differently.

The terms defined in a commonly used dictionary should be understood as the context, and should not be understood ideally or excessively unless defined differently.

Hereinafter, preferred embodiments of the present invention will be explained referring to figures.

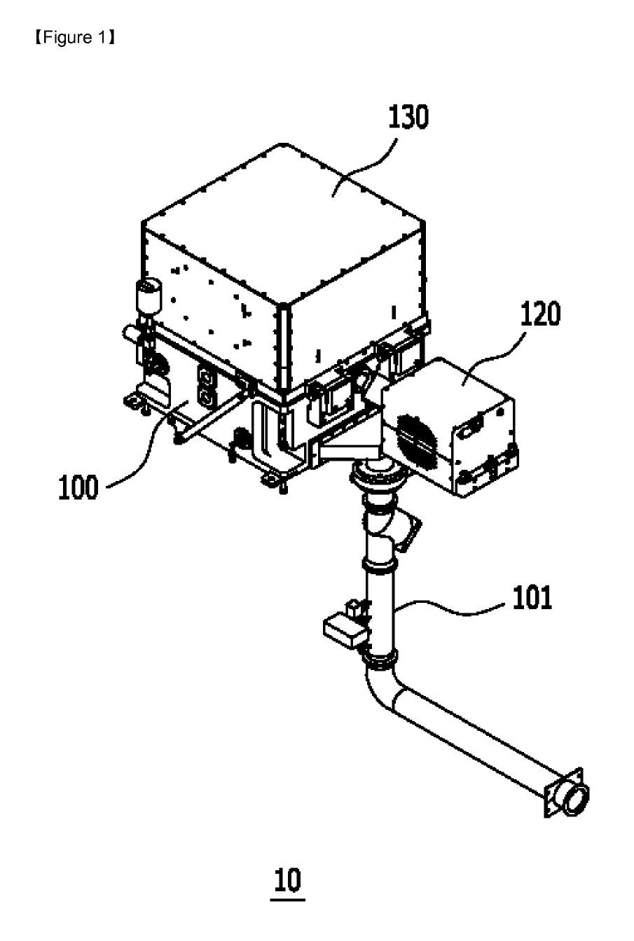

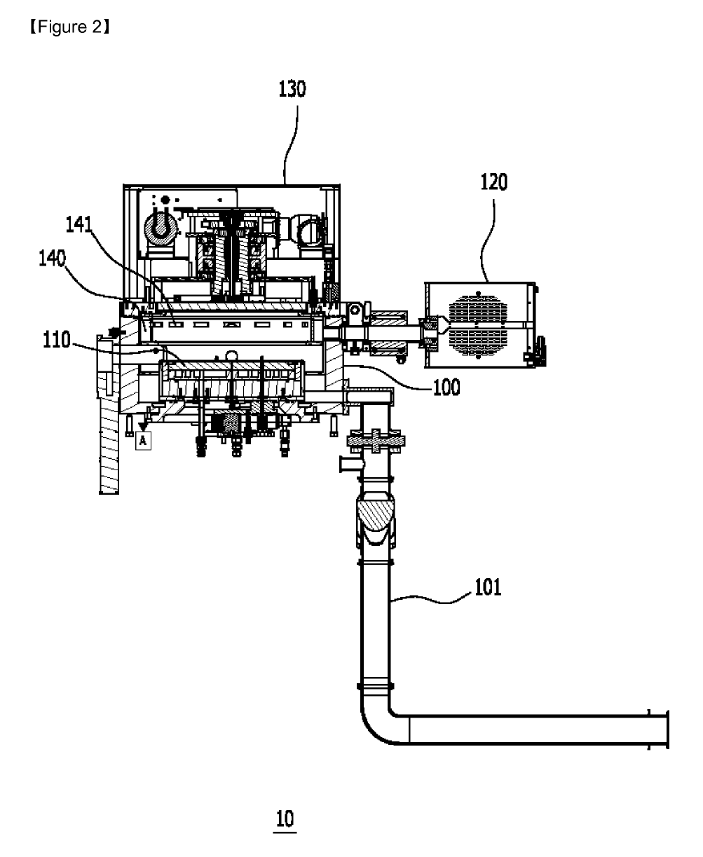

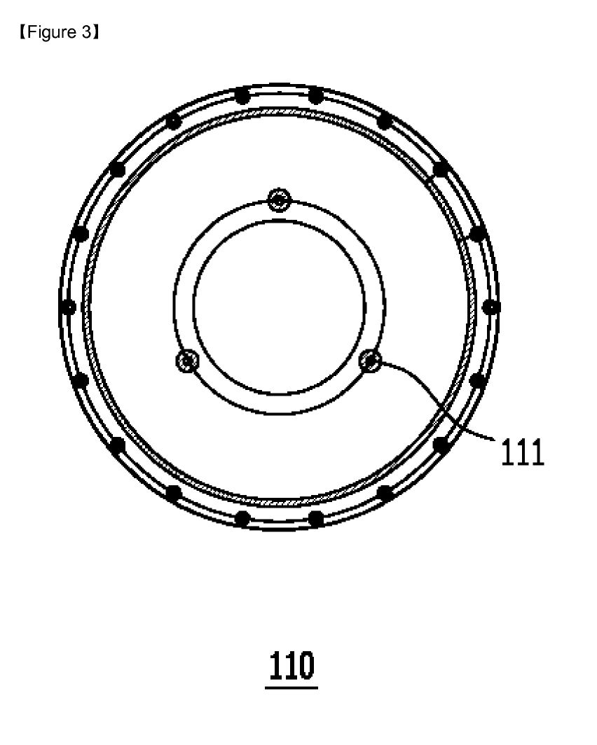

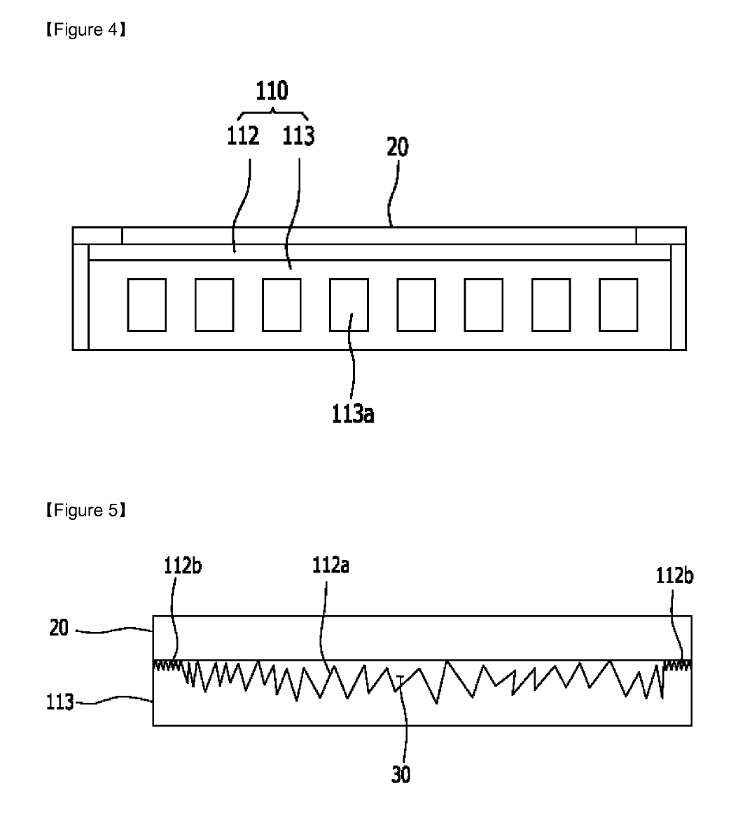

FIG. 1 is a perspective view showing a wafer etching apparatus according to an embodiment of the present invention, FIG. 2 is a cross-sectional view showing inside of a wafer etching apparatus according to an embodiment of the present invention, FIG. 3 is a plan view showing a chuck according to an embodiment of the present invention, FIG. 4 is a cross-sectional view for explaining a chuck according to an embodiment of the present invention, and FIG. 5 is a figure for explaining a state where a minute space is formed between a wafer and a chuck.

Referring to FIG. 1 to FIG. 5, a wafer etching apparatus 10 according to an embodiment of the present invention includes a process chamber 100, a chuck 110, a first plasma unit 120 and a second plasma unit 130.

The process chamber 100 includes an exhaust outlet 101, and inner surfaces of the process chamber 100 are covered by a ceramic material.

The chuck 110 is disposed in the process chamber 100. The chuck 110 has a circular disk shape, and a wafer 20 is disposed on the chuck 110. The chuck 110 has a plurality of pin holes 111, through which pins lifting up the wafer 20 pass. The chuck 110 includes an upper body 112 and a lower body 113. For example, the upper body 112 includes a ceramic material and the lower body 113 includes aluminum. The upper body 112 supports the wafer 20, and an upper surface of the upper body 110, on which the wafer 20 is disposed, has a roughness so that minute space 30 is generated between the upper surface and the wafer 20. Helium gas for cooling is induced into the minute space 30 to cool down the wafer 20. The upper surface of the upper body 112 may have a minute space portion 112a and a contact portion 112b. The minute space portion 112a is formed at a portion except a peripheral region to have roughness so that the minute space 30 is generated between the wafer 20 and the minute space portion 112a. The contact portion 112b is formed at the peripheral region such that the contact portion 112b has more dense and minute surface than the minute space portion 112b to prevent helium gas for cooling from being deflated from the minute space 30.

The upper body 112 is disposed on the lower body 113 and the lower body 113 includes a water providing line 113a formed inside thereof. Additionally, the lower body 113 is electrically connected to a DC power (not shown). As described above, the chuck 110 of the wafer etching apparatus 10 according to an embodiment of the present invention has the upper surface with the roughness so that the minute space 30 is formed between the upper surface and the wafer 20 to induce helium gas for cooling down the wafer 20.

As described above, the chuck 110 according to an embodiment of the present invention applies helium gas for cooling down the wafer 20 not through a groove but through minute space 30 formed between the upper surface and the wafer 20 so that plasma is prevented, which is generated in a space between the groove and the wafer. Therefore, wafer damage by unwanted plasma can be reduced.

The first plasma unit 120 is combined to the process chamber 100, and sprays first etching gas of a number of Torr (one to ten Torr) into the process chamber 100 to etch the wafer 20 with a large surface in high speed. For example, the first plasma unit 120 may be a remote plasma unit having a ferrite core with an inductive coil. The first etching gas may include NF₃, SF₆, O₂, N₂, Ar, etc.

The second plasma unit 130 is connected to the process chamber 100, and sprays second etching gas of a number of mTorr to hundreds of mTorr, which is lower in comparison with the first plasma unit 120, into the process chamber 100 to remove stress of the wafer 20, to form copper (Cu) pillar, and to etch the surface of the wafer 20 to form wanted roughness. For example, the second plasma unit 130 may be a capacitively coupled plasma (CCP) unit generating plasma between two parallel plates. Alternatively, the second plasma unit 130 may be an inductively coupled plasma (ICP) unit generating plasma through coil. The second etching gas may include No, Ar, NF₃, etc.

On the other hand, the wafer etching apparatus according to an embodiment of the present invention further include a duct 140 with a plurality of gas outlets 141 through which the first etching gas is uniformly sprayed into the process chamber 100 from the first plasma unit 120. The duct 140 has a torus structure with a donut shape, and the plurality of gas outlets 141 is formed at inner side of the duct 140. For example, the plurality of gas outlets 141 may be formed to have hole shape with slot shape. The duct 140 distributes radical generated by the first plasma unit 120 toward the wafer 20. The plurality of gas outlets 141 of the duct 140 may have different size in order to more uniformly spray the first etching gas onto the wafer 20 generated by the first plasma unit 120. For example, a gas inlet portion of the duct 140 is relatively higher in pressure so that the gas outlets 141 near the gas inlet is small in size and size of the gas outlets 141 increases as the gas outlets 141 becomes more distant from the gas inlet.

Hereinafter, a wafer etching method using the wafer etching apparatus according to an embodiment of the present invention will be explained referring to FIG. 1 to FIG. 7.

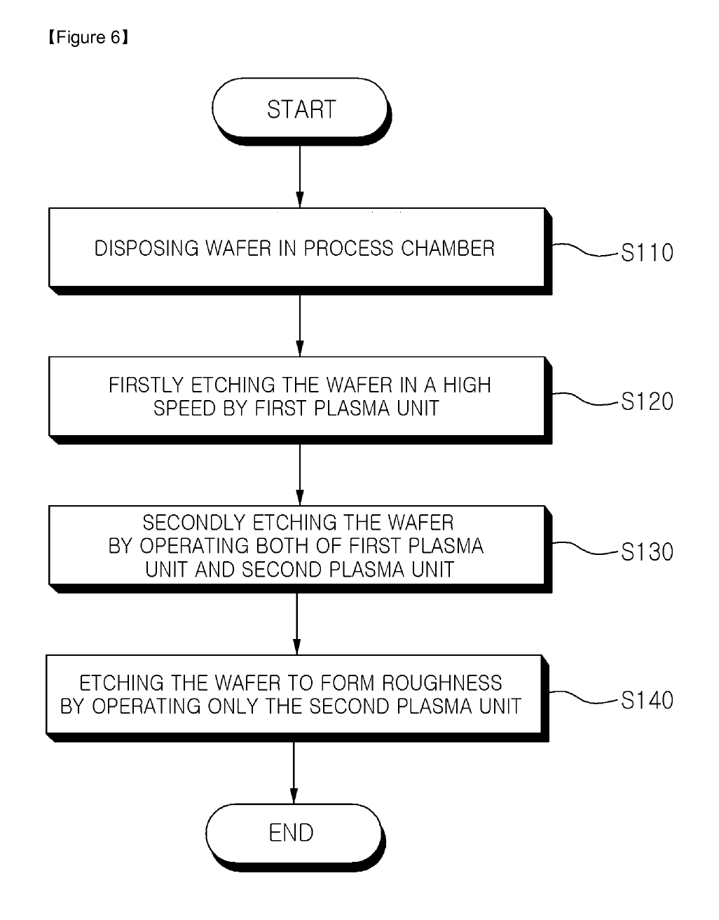

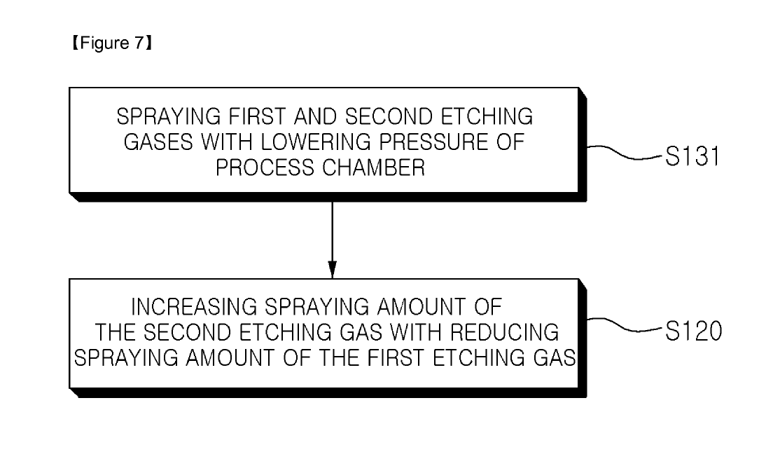

FIG. 6 is a flow chart of a wafer etching method using a wafer etching apparatus according to an embodiment of the present invention, and FIG. 7 is a flow chart for explaining a step of wafer etching by spraying first and second etching gas simultaneously into a process chamber.

Referring to FIG. 1 to FIG. 7, in order to etch a wafer 20 by using the wafer etching apparatus according to an embodiment of the present invention, the wafer 20 is disposed in the process chamber 100 (step S110). In detail, the wafer 20 is disposed on the chuck 110 in the process chamber 100.

After the wafer 20 is disposed, the first etching gas of high pressure of 1˜10 Torr is sprayed into the process chamber 100, in which the wafer 20 is disposed, through the first plasma unit 120 to firstly etch the wafer 20 with large surface (step S120). In this case, NF₃ gas or SF₆ gas is used as the main gas of the first etching gas such that fluorine (F) reacts with silicon (Si) of the wafer to etch the wafer 20.

After the wafer 20 is firstly etched using the first etching gas, the second etching gas, of which pressure is lower than the first etching gas spayed by the first plasma unit 120, is sprayed into the process chamber 100 by the second plasma unit 130 to secondly etch the wafer 20 together with the first etching gas (step S130). In this case, the second plasma unit 130 does not generate plasma in high pressure in which the first plasma unit 120, which is a remote plasma unit, generates plasma, but the second plasma unit 130 generates plasma even in high pressure when radical F* exists in the process chamber through the first etching gas.

For explaining the step of S130 in more detail, the second etching gas is sprayed by the second plasma unit 130 together with the first etching gas (S131) with lowering pressure of the process chamber 100. After spraying the first and second etching gas into the process chamber 100, the spraying amount of the second etching gas is gradually increased to etch the wafer 20 with gradually lowering the pressure of the chamber 100 and gradually reducing the spraying amount of the first etching gas (step S132).

The reason why the first and second etching gases are simultaneously sprayed into the chamber 100 to etch the wafer 20 is that a conventionally used end point detector (EPD) or a conventionally used optical emission system (OES) cannot be used since light vanishes so quickly with only the first etching gas or the remote plasma. Therefore, the second etching gas of which light exists relatively longer is sprayed together with the first etching gas into the process chamber 100 to generate plasma so that timing for stopping the etching of the wafer 20 can be detected by using the end point detector (EPD) and the optical emission system (OES) in a step of S140 that will be explained.

After etching the wafer 20 by simultaneously spraying the first and second etching gases into the process chamber 100, the operation of the first plasma unit 120 is stopped and only the second etching gas is sprayed into the process chamber 100 through the second plasma unit 130 not only to remove stress of the wafer 20 and to form copper pillar but also to form roughness on the surface of the wafer 20 (step S140).

When the pressure of the process chamber 100 is lowered to the pressure in which plasma may be generated by the second plasma unit 130, spraying of the first etching gas is stopped. And, the second etching gas is sprayed uniformly, when spraying of the first etching gas is stopped.

According to the wafer etching apparatus and the wafer etching method using the wafer etching apparatus of an embodiment of the present invention, the wafer etching apparatus includes the first plasma unit 120 that is one of the capacitively coupled plasma unit or the inductively coupled plasma unit together with the second plasma unit 130 that is a remote plasma unit having a ferrite core with an inductive coil to firstly etch a wafer 20 in a high speed by the first plasma unit 120 and then not only to remove stress of the wafer 20 and to form the copper pillar by the second plasma unit 130 but also to secondly etch the wafer 20 in order to form roughness at the surface of the wafer 20 so that etching of the wafer 20 can be performed in a high speed.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A wafer etching apparatus comprising:
a process chamber having a chuck disposed therein to support a wafer;
a first plasma unit being connected to the process chamber and spraying a first etching gas of high pressure into the process chamber to etch the wafer with large surface in a high speed; and
a second plasma unit being connected to the process chamber and spraying a second etching gas of low pressure into the process chamber to remove stress of the wafer, to form copper pillar, and to etch the surface of the wafer in order to form wanted roughness.

2. The wafer etching apparatus of claim 1, wherein the first plasma unit is a remote plasma unit having a ferrite core with inductive coil.

3. The wafer etching apparatus of claim 1, wherein the first etching gas comprises at least one of NF₃ and SF₆.

4. The wafer etching apparatus of claim 1, wherein the second plasma unit is a capacitively coupled plasma (CCP) unit generating plasma between two parallel plates.

5. The wafer etching apparatus of claim 1, wherein the second plasma unit is a an inductively coupled plasma (ICP) unit generating plasma through coil.

6. The wafer etching apparatus of claim 1, further comprising a duct with a plurality of gas outlets through which the first etching gas is uniformly sprayed into the process chamber from the first plasma unit.

7. The wafer etching apparatus of claim 1, wherein the chuck is disposed in the process chamber, and having an upper surface with irregular roughness to generate minute space between the upper surface and the wafer, through which a cooling gas is provided to the wafer to cool down the wafer.

8. The wafer etching apparatus of claim 7, wherein the chuck comprises:
an upper body supporting the wafer, the upper body having the upper surface with irregular roughness; and
a lower body, on which the upper body is disposed, the lower body including a water providing line formed inside thereof.

9. The wafer etching apparatus of claim 8, wherein the upper surface of the upper body comprises:
a minute space portion formed at a portion except a peripheral region to have irregular roughness so that the minute space is generated between the wafer and the minute space portion; and
a contact portion formed at the peripheral region such that the contact portion has more dense and minute surface than the minute space portion to prevent the cooling gas for cooling from being deflated from the minute space.

10. A wafer etching method comprising:
etching a wafer with large area by spraying a first etching gas with high pressure through a first plasma unit into a process chamber in which a wafer is disposed;
etching the wafer by spraying a second etching gas with low pressure through a second plasma unit into the process chamber together with the first etching gas; and
removing a stress of the wafer, forming a copper pillar and etching the wafer to form wanted roughness on a surface of the wafer through only the second etching gas at the same time by stopping an operation of the first plasma unit.

11. The wafer etching method of claim 1, wherein etching the wafer by spraying the first etching gas and the second etching gas into the process chamber comprises:
spraying the second etching gas into the process chamber through the second plasma unit together with the first etching gas, with lowering pressure of the process chamber; and
gradually increasing the spraying amount of the second etching gas is gradually increased to etch the wafer, with gradually lowering the pressure of the chamber and gradually reducing the spraying amount of the first etching gas.

12. The wafer etching method of claim 10, wherein spraying of the first etching gas is stopped, when the pressure of the process chamber is lowered to the pressure in which plasma may be generated by the second plasma unit.

13. The wafer etching method of claim 10, wherein the second etching gas is sprayed uniformly, when spraying of the first etching gas is stopped.
